(19) United States
(12) Patent Application Publication
(10) Pub. No.: US 2024/0423090 A1
(43) Pub. Date: Dec. 19, 2024

(54) DEVICE FOR PRODUCING ELECTRICITY

(71) Applicant: TFG GLOBAL POWER LIMITED, Bishop’s Stortford Hertfordshire (GB)

(72) Inventors: Fergus Julian Edward Crawley, Milton Keynes Buckinghamshire (GB); Zhenhua Luo, Milton Keynes Buckinghamshire (GB); Zaharaddeen Ali Hussaini, Derby Derbyshire (GB); Christopher Leslie Sansom, King's Lynn Norfolk (GB)

(21) Appl. No.: 18/718,293

(22) PCT Filed: Dec. 5, 2022
(86) PCT No.: PCT/EP2022/084437

§ 371 Date: Jun. 10, 2024

(30) Foreign Application Priority Data
Dec. 9, 2021 (GB) 2117824.9

(51) Int. Cl. H10N 10/13; H10N 10/17

(52) U.S. Cl. CPC H10N 10/13; H10N 10/17

(57) ABSTRACT

A static thermal generator for the generation of electricity from heat includes a first hot plate adjacent to a heating channel and a first cool plate adjacent to a cooling channel, wherein the central portion of the first hot plate and the central portion of the first cool plate are separated by a space configured to house a thermoelectric module. The heating channel is configured to carry a hot fluid and the cooling channel is configured to carry a cool fluid. The first hot plate and the first cool plate are arranged wherein a central portion of the first hot plate and a central portion of the first cool plate overlap one another and are positioned perpendicular to one another. When the hot fluid reaches an end of the heating channel, the hot fluid exits the heating channel and is pumped to a position where the hot fluid is re-heated.

### FIELD OF INVENTION

The present invention is in the field of the generation of electrical power. Specifically, the present invention is in the field of the generation of electrical power from heat.

### BACKGROUND

There is a well-known need to generate energy from renewable sources. The need for this is both to reduce carbon emissions, but also to provide energy sources in places that either have little wealth/resources or where it is difficult to supply traditional fuels.

Renewable energy sources include tidal, solar, wind and other such energy generation. In countries with high amounts of sun and thermal energy there is a need for an energy generation device that can make use of heat energy and convert it to electrical energy. Further there is a need to make this device have no moving parts so that the lifespan of the device is increased and so that less maintenance is needed. This may allow the device to be used in areas where specialty maintenance skills may not be common.

US2005/0126618 describes a device for producing electric energy with a bank that consists of a plurality of thermocouples. Similarly, US2005/0087222 describes a device for producing electrical energy that include a plurality of thermocouples. Whilst these documents describe a device for the generation of electricity from heat that involves a lack of moving parts, they can be improved. This is particularly the case in terms of efficiency. The object of the present application is therefore to offer an improved device with a higher level of efficiency in the generation of electrical power from heat.

### STATEMENT OF INVENTION

Aspects of the invention are set out in the independent claims. Optional features of the invention are set out in the dependent claims.

According to a first aspect there is provided a static thermal foil generator for the generation of electricity from heat, wherein the thermal foil generator comprises a first hot plate, adjacent to a heating channel, the heating channel configured to carry a hot fluid such that the first hot plate is configured to be heated by the hot fluid, a first cool plate, adjacent to a cooling channel, the cooling channel configured to carry a cool fluid such that the first cool plate is configured to be cooled by the cool fluid. The first hot plate comprises proximal, central and distal portions, and the first cool plate comprises proximal, central and distal portions, wherein the first hot plate and first cool plate are arranged such that the central portion of the first hot plate and the central portion of the first cool plate overlap one another. The first hot plate and the first cool plate are positioned perpendicular to one another, wherein the central portion of the first hot plate and the central portion of the first cool plate are separated by a space configured to house a thermoelectric module. This is advantageous for many reasons. Principally, the arrangement of the hot plate and the cold plate enables there to a be a region with a temperature gradient in which the thermoelectric module may be positioned. This allows for the generation of energy. Moreover, the perpendicular arrangement of the plates, with the central portions overlapping one another has been found to lead to a particularly efficient creation of energy.

Optionally, one side of the thermoelectric module is cooled by the first cool plate, and the other side of the thermoelectric module is heated the first hot plate. Advantageously this may create a temperature gradient.

Optionally, the space is configured such that when in situ said thermoelectric module contacts both the first hot plate and the second cool plate. Advantageously this increases the amount of heat energy transferred, and therefore increases the efficient of electrical energy production.

Optionally, the first hot plate comprises chambers, optionally wherein said chambers contain a vacuum, or optionally wherein said chambers contain a fluid or vapour, optionally wherein said vapour is at a low pressure, optionally wherein the vapour comprises water droplets. Advantageously chambers may allow for the hot plate to conduct heat very efficiently, and therefore heat up in response to being near a source of heat. Moreover, this may produce a homogenous temperature for the hot plate (or the portion covered by said chambers). This homogeneity may also increase the efficiency of the system.

Optionally, the first cool plate comprises chambers, optionally wherein said chambers contain a vacuum, or optionally wherein said chambers contain a fluid or vapour, optionally wherein said vapour is at a low pressure, optionally wherein the vapour comprises water droplets. Advantageously chambers may allow for the cold plate to be cooled very efficiently. Moreover, this may produce a homogenous temperature for the cold plate (or the portion covered by said chambers). This homogeneity may also increase the efficiency of the system.

Optionally, the static thermal foil generator further comprises a spacer positioned between the first hot plate and the first cool plate. This may prevent the plates touching (e.g. due to deformation over time) which would reduce the thermal gradient experienced by the thermoelectric element. This may therefore increase the lifespan of the device.

Optionally, the static thermal foil generator further comprises a first gasket and/or a spacer between the first hot plate and the first cool plate. This may prevent the plates touching (e.g. due to deformation over time) which would reduce the thermal gradient experienced by the thermoelectric element. This may therefore increase the lifespan of the device.

Optionally, the static thermal foil generator further comprises a second hot plate comprising a proximal portion, central portion and distal portion, positioned in line with the first hot plate, and vertically offset from the first hot plate, wherein the first cool plate is positioned between the first hot plate and the second hot plate. Advantageously the second hot plate may allow for a second region with a thermal gradient to be created. This means that electrical energy may be produced from two sources. This greatly increases the efficiency of the system, and the amount of heat energy that can be converted to electrical energy per unit time.

Optionally, the second hot plate and first cool plate are arranged such that the central portion of the second hot plate and the central portion of the first cool plate overlap one another. The second hot plate and the first cool plate are positioned perpendicular to one another, wherein the central portion of the second hot plate and the central portion of the first cool plate are separated by a space configured to house a second thermoelectric module. Advantageously this arrangement provides a second region in the same arrangement as the first. By placing the apparatus in the same arrangement this is very space efficient, as well as being efficient at producing electrical energy.

Optionally, the static thermal foil generator further comprises a second cool plate comprising a proximal portion, central portion and distal portion, positioned in line with the first cool plate, and vertically offset from the first cool plate, wherein the first hot Advantageously the second cool plate may allow for a second (or third if in combination with the second hot plate) region with a thermal gradient to be created. This means that electrical energy may be produced from two/three sources. This greatly increases the efficiency of the system, and the amount of heat energy that can be converted to electrical energy per unit time. The combination of both the second cool plate and second hot plate together is particularly advantageous. The number of thermoelectric modules is one less than the number of plates (as long as they are alternating hot/cold) and so increasing the number of plates means that the ratio of thermoelectric modules to plates increases. This makes the system as a whole more advantageous.

Optionally, the second cool plate and first hot plate are arranged such that the central portion of the second cool plate and the central portion of the first hot plate overlap one another. The second cool plate and the first hot plate are positioned perpendicular to one another, wherein the central portion of the second cool plate and the central portion of the first hot plate are separated by a space configured to house a third thermoelectric module. Advantageously this arrangement provides a second region in the same arrangement as the first. By placing the apparatus in the same arrangement this is very space efficient, as well as being efficient at producing electrical energy.

Optionally, the static thermal foil generator further comprises a first thermoelectric module, optionally comprising a second thermoelectric module, and further optionally comprising a third thermoelectric module.

Optionally, the central portion of the plates is profiled such that when overlapping one another one or more channels are created at the edge of the central portion, optionally wherein electric cables are positioned within the channels to connect to thermoelectric modules. Advantageously, this allows the cabling to be positioned internally and out of the way, making the device operate similar to a black box to the user, and therefore making operation and maintenance simple to the user.

Optionally, the heating channel passes from the first hot plate to the second hot plate. Advantageously, this means that heat not transferred through the first thermoelectric element (and so otherwise wasted) may be used in the second thermoelectric element.

Optionally, the cooling channel passes from the first cool plate to the second cool plate. This means that where the cooling channel has not been heated at the first thermoelectric element the remaining cool fluid may be used to generate electricity at the second cool plate.

Optionally, the static thermal foil generator further comprises rods to connect the plates together such that they are secure. Advantageously this may increase the lifespan of the device. These rods may be manufactured from low thermal conductors (e.g. not metals) such that the hot and cold plates are thermodynamically separated.

Optionally, the apparatus is within a sealed shell. This may advantageously protect the internal workings of the device from detritus. For example, if the device is operating in an area with sand, then granules may otherwise enter the device and potential cause damage to the device.

Optionally, the plates are formed form copper or aluminium. Advantageously these materials have high thermal conductivities.

Optionally, the heating fluid is oil, and optionally wherein the cooling fluid is water. These fluids are both economically efficient to use, as well as having good flow, and heat conduction. Oil may be more preferable as it may have a longer lifespan without causing corrosion in some circumstances.

Optionally, the heating fluid transfers waste heat from an industrial process, or wherein the heating fluid is heated via energy from the sun. For example, a plate may be heated by the sun to heat the heating fluid. Alternatively, a heat pump, or conductive surface, or other suitable means may transfer excess heat from an industrial process to the thermal foil generator.

Optionally, the static thermal foil generator further comprises a vat of heating fluid positioned adjacent the inside of the sealed shell, such that the heating fluid is warmed by energy from the sun. The outside may be painted black to absorb as much of the heat form the sun as possible in some embodiments.

This may be an efficient way of harvesting thermal energy for conversion to electricity.

Optionally, the thermoelectric module is configured to transfer heat energy to electrical energy in the presence of a temperature differential.

### BRIEF DESCRIPTION OF FIGURES

FIG. 1 shows a single plate (either hot or cold) that may be used as a basis for the present device. This is shown in perspective view, plan view, side view, and end on.

FIG. 2 shows a plate (either hot or cold) with a number of chambers within the plate.

FIG. 3 shows a perspective view of one embodiment in which the plates are positioned on top of one another, perpendicular to one another, with an overlapping section in the central portion.

FIGS. 4a and 4b are plan views of the hot and cold plates in the arrangement of FIG. 3, with a central part of the plates profiled such that in situ channels are created to allow electric cables or wires to be positioned in. FIG. 4b shows a thermoelectric module in place.

FIG. 5 is a schematic diagram of an embodiment with two cold plates and a hot plate and two thermoelectric modules (referred hereto as thermoelectric generators TEG). The wiring is shown as being attached to the thermoelectric modules.

FIG. 6 is a perspective view of one embodiment of the present invention with spacers separating the hot and cold plates in one direction.

FIG. 7 is a perspective view of one embodiment in which spaces separate the hot and cold plates in both directions, and rods are present to hold the plates in situ.

FIG. 8 is a cross section of the device showing the flow of hot fluid in the heating channel, and the conduction of heat across the hot plates.

FIG. 9 is a cross section of the device showing the flow of cold fluid in the cooling channel and the conduction of heat drawing heat from the cold plates.

FIG. 10 shows heat flow in both the hot and cold plates.

FIG. 11 shows the arrangement of the thermoelectric modules within the device.

FIG. 12 shows a cross section of a complete device.

### DETAILED DESCRIPTION

The Figures described below show a static thermal foil generator for the generation of electricity from heat, wherein the thermal foil generator comprises a first hot plate, adjacent to a heating channel, the heating channel configured to carry a hot fluid such that the first hot plate is configured to be heated by the hot fluid, and a first cool plate, adjacent to a cooling channel, the cooling channel configured to carry a cool fluid such that the first cool plate is configured to be cooled by the cool fluid. The first hot plate comprises proximal, central and distal portions, and the first cool plate comprises proximal, central and distal portions, and wherein the first hot plate and first cool plate are arranged such that the central portion of the first hot plate and the central portion of the first cool plate overlap one another. The first hot plate and the first cool plate are positioned perpendicular to one another, wherein the central portion of the first hot plate and the central portion of the first cool plate are separated by a space configured to house a thermoelectric module.

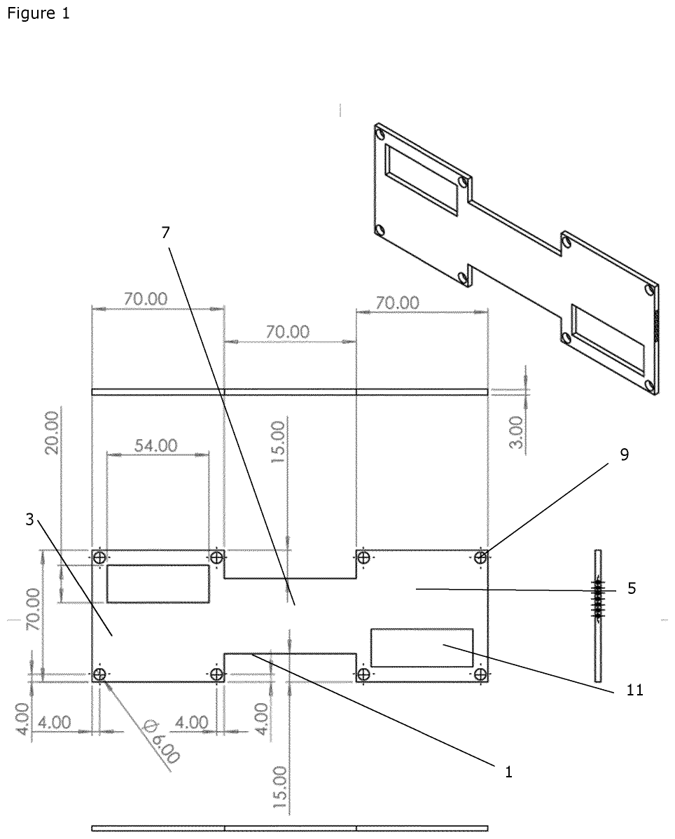

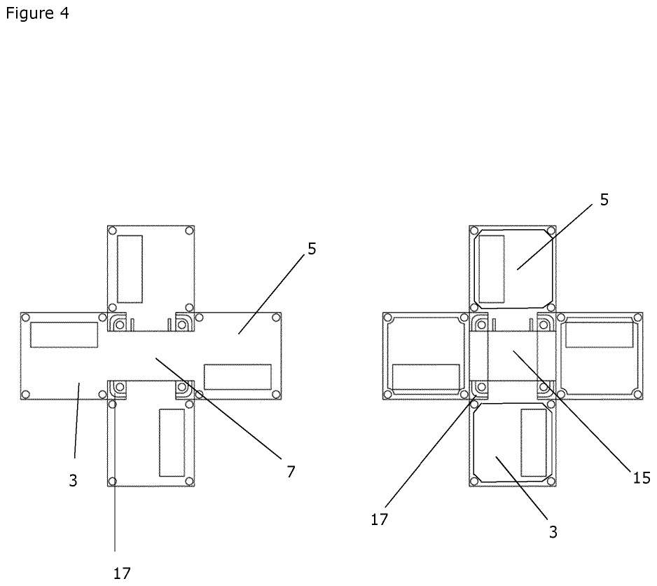

FIG. 1 shows a plate 1. This plate may either be configured to be a cold plate of a hot plate. The plate comprises a proximal end 3 and a distal end 5 with a central portion 7. The central portion 7 is shown as having a smaller width than the proximal 3 and distal 5 ends (this is an optional feature). The proximal 3 and distal 5 ends are each shown as having four holes 9, one at each corner. These holes 9 are configured such that a rod may be pushed through each holes, so as to keep the plate in situ during use. The central 7 portion having a lower width allows for the creation of channels for electrical cabling once the plates overlie one another (as shown in FIGS. 4a and 4b). The plate 1 of FIG. 1 is shown as being substantially planar such that it extends in the x-y plane, but is substantially thinner in the z plane. In one embodiment the plate may extend 210 mm in the X direction, 70 m in the Y direction and 3 mm in the Z direction. This increases the thermal conductivity of the plate 1 as the mass of the plate is lower due less matter being used to construct the plate 1. A window 11 is also shown positioned on both the proximal and distal ends of the plate. The window may be used for the heating or cooling channel to pass through. This enables the heating and cooling channels to pass through numerous layers of plates within the thermal foil generator. The window 11 may be any size. In ne embodiment the window may be 54 mm by 20 mm. The offset windows 11 may also be referred to as baffles and may be used to increase turbulent flow which should aid heat transfer from liquid to metal. Alternatively, the channels may pass around the plates, and in such embodiments no window may be required. The plates 1 may be formed from any thermally conductive material such as a metal. Copper and aluminium are thermally conductive and economically efficient materials due to their relatively low cost. Alternatively, gold, silver or platinum may be used due to their high thermal conductivity.

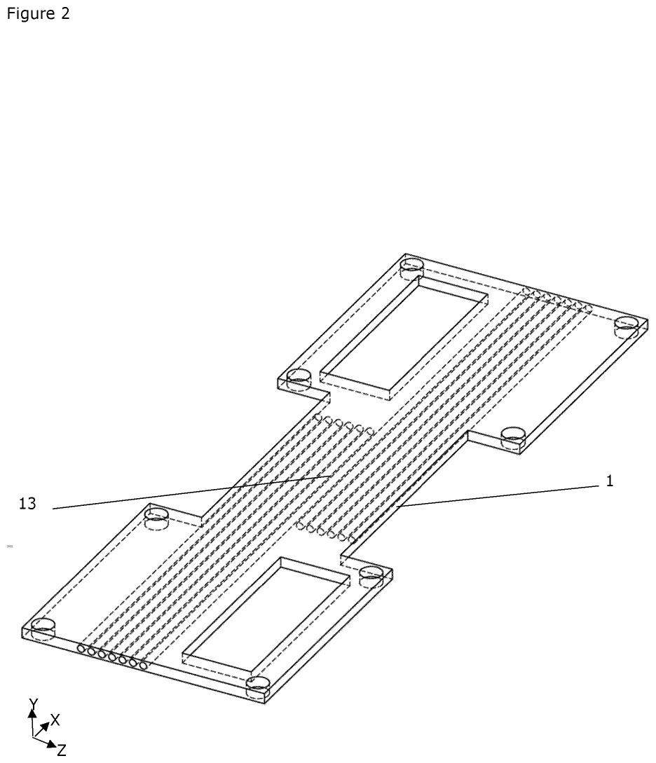

FIG. 2 shows the plate 1 of FIG. 1. Optional chambers 13 are also shown in the structure of the plate 1 These chambers may contain a vacuum, or optionally wherein said chambers 13 contain a fluid or vapour. The vapour may be at a low pressure, and may comprise water droplets. This may be formed in any suitable way such as adding water vapour in a vacuum, while the ends are being welded closed, the small amount of liquid is heated up to steam, and then the pipe is closed. When the system cools down, the heated vapour inside attempts to contract and condense to liquid, but this creates internal pressure. Thus the vapour is trapped in low pressure. Other suitable techniques may also be used.

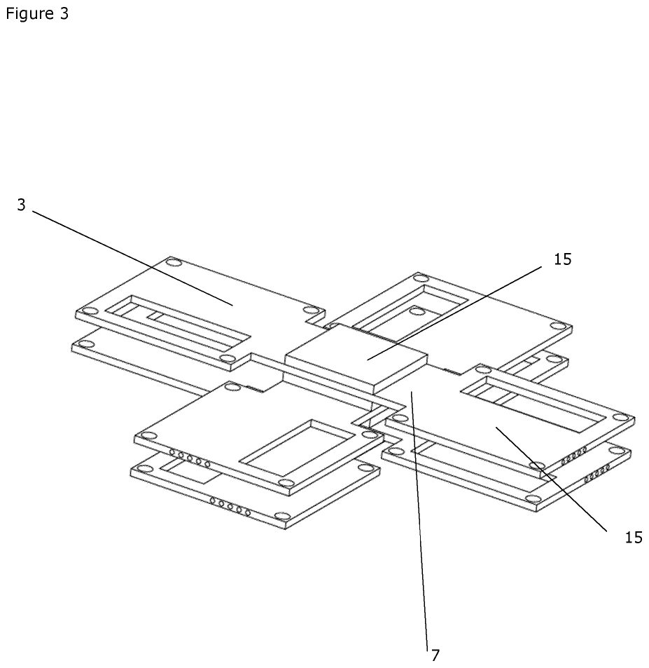

FIG. 3 shows a perspective view of one embodiment in which the plates 1 are positioned on top of one another, perpendicular to one another, with overlap in the central portion 7. In this case two hot plates and two cold plates are in use. However, in other embodiments a single hot plate and a single cold plate may be used, or any number of hot and cold plates may be used (as long as either there is one more hot plate than cold plate, there is the same number of hot and cold plates, or there is one more cold plate than hot plate).

Three thermoelectric modules 15 are shown. The first of these is positioned atop the top most plate. In practice a thermoelectric module will be placed between two plates-however in this instance an additional thermoelectric module 15 is shown for illustrative purposed (a further plate 1 may be placed on top of the top most thermoelectric module 15). The thermoelectric modules 15 are configured to convert thermal energy to electricity. Specifically, the thermoelectric modules convert a thermal gradient (that is a temperature differential) between their top and bottom surfaces into electrical energy. This is because thermal energy therefore passes from one side of the thermoelectric module 15 to the other, and so there is a movement of energy through the module 15. The thermoelectric module 15 then uses this movement of energy to convert this energy to electrical energy. It is noted that the device shown herein may be provided to a consumer without the thermoelectric module, and the thermoelectric module(s) 15 may be provided separately. Any suitable thermoelectric module may be used. Examples of suitable modules include the TCS TEG rev A Version 1, or the GM250-127-14-16 thermoelectric generator module.

The overlapping arrangement of the plates 1 is particularly advantageous. The centre of the hot and cold plates overlap (this is where the thermoelectric modules 15 are situated as there is a thermal gradient between the plates). However, as the plates 1 are situated perpendicular to one another the proximal 3 and distal 5 ends of the hot and cold plates do not overlap. This means that the proximal 3 and distal 5 ends of the plates are situated away from each other. This means that the proximal 3 and distal 5 ends of the hot and cold plates are less likely to cause heat transfer between the plates 1. Heat transfer that is not through the thermoelectric module 15 decreases efficiency as it wastes the thermal energy. Therefore, the perpendicular arrangement of the hot and cold plates increases the efficiency of the device.

FIGS. 4a and 4b are plan views of the hot and cold plates in the arrangement of FIG. 3, with a central part 7 of the plates 1 profiled such that in situ channels 17 are created to allow electric cables or wires to be positioned in. FIG. 4b shows a thermoelectric module 15 in place. These channels 17 are formed from the narrowed central 7 width of the plates 1 as shown in FIG. 1. The cabling running through the centre of the device may be advantageous as it may enable the cables for connecting the thermoelectric modules 15 to an external device to all exit in the same manner, and allow the cables to be easily managed. This may make any maintenance simpler, and may reduce the chance of failure do to wear of an electrical cable.

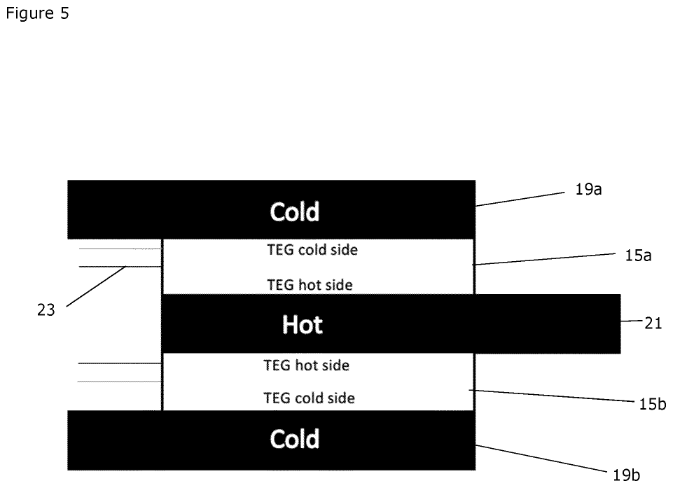

FIG. 5 is a schematic diagram of an embodiment with two cold plates 19 and a hot plate 21 and two thermoelectric modules 15 (referred hereto as thermoelectric generators TEG). The wiring 23 is shown as being attached to the thermoelectric modules 15. As can be seen the first thermoelectric module 15a is between a top-most cold plate 19a, and a hot plate 21 (situated in the centre of the arrangement). The second thermoelectric module 15b is situated between the hot plate 21 and the bottom-most cold plate 19b. As can be seen this means that thermoelectric modules 15 must be arranged in an alternating function (i.e. the other way up to the neighbouring thermoelectric module). The wiring shows that this means that the positive and negative wiring 23 must be inverted in conjunction with the inversion of the thermoelectric module 15. In this example in the first thermoelectric module 15 the upper wire is a positive, and the lower is negative. Of course this may be reversed dependent on how the thermoelectric module, and the circuit is sits in is engineered. In this embodiment however regardless of which wire is positive in the first thermoelectric module in the second thermoelectric module this arrangement is reversed.

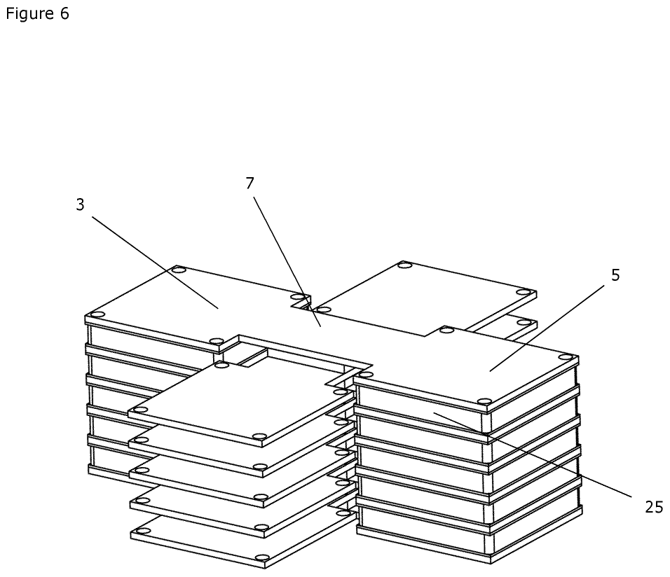

FIG. 6 is a perspective view of one embodiment of the present invention with spacers 25 separating the hot and cold plates in one direction. These spacers 25 may aid with sealing, and be formed of thermal insulators and therefore reduce any thermal transfer further (however this is not an essential feature as in some embodiments the side channels are the same temperature). Examples of suitable materials include nitrile rubber or cork.

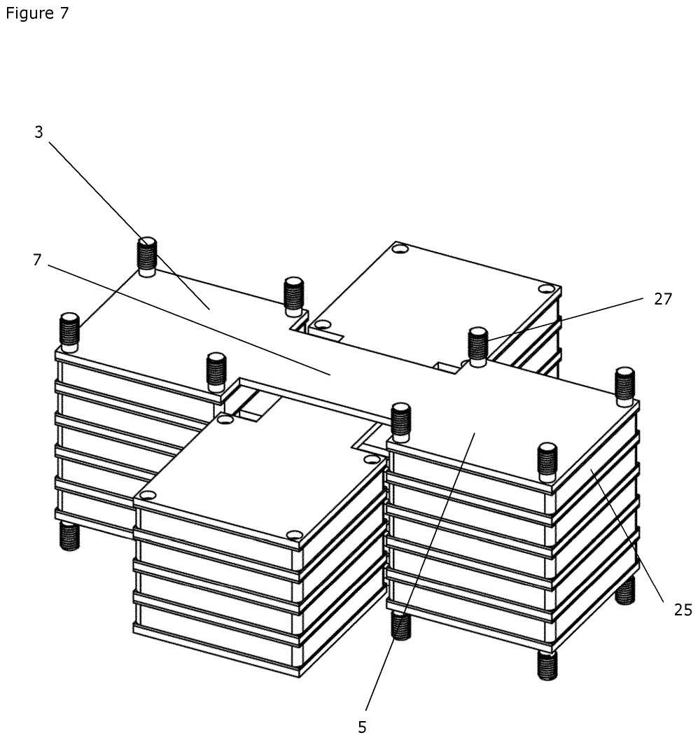

FIG. 7 is a perspective view of one embodiment in which spacers 25 separate the hot and cold plates in both directions, and rods 27 are present to hold the plates in situ. These spacers 25 may be formed of thermal insulators and therefore reduce any thermal transfer further. The rods 27 may also be formed of materials that have a low thermal conductivity. The rods 27 may also provide structural support, and so may be made from a material with a high strength density. The rods may ensure that the plates do not move relative to one another when in transit, or in situ. Any movement of the plates 1 may reduce the thermal efficiency of the device. FIG. 7 only shows rods 27 in one type of plate (e.g. hot plates only). However, the rods may be used for one of or both of the hot and cold plates. The rods 27 may be metallic.

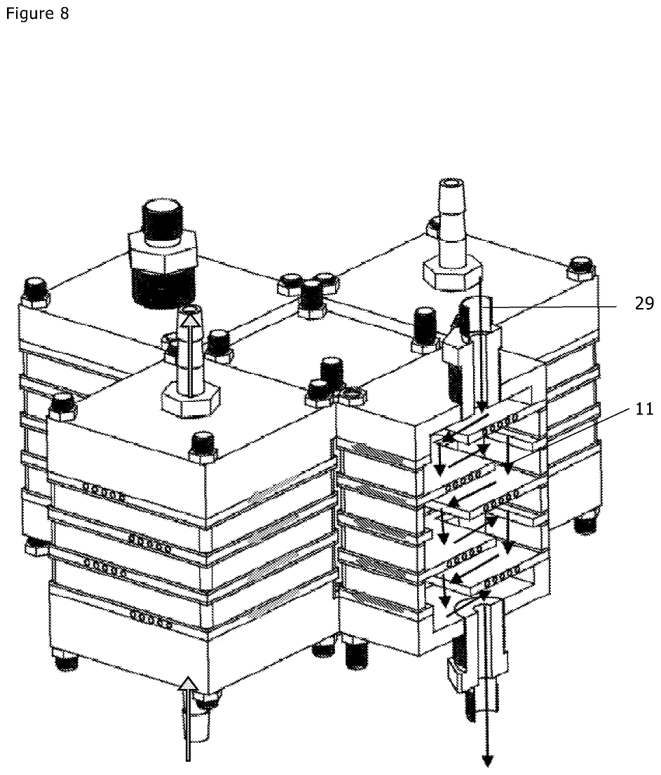

FIG. 8 is a cross section of the device showing the flow of hot fluid 29 in the heating channel, and the conduction of heat across the hot plates 21. The gaps shown in the plates correspond to the window 11 shown in the plates 1 in FIG. 1. In FIG. 8 the cross section extends into the window 11 of the hot plates 21. FIG. 8 shows that hot fluid 29 is configured to flow through a heating channel. The heating channel passes through the window 11 of each hot plate in the device. The heating channel is configured to enlarge the cross sectional area in which the heating channel is in thermal contact with the hot plate 29 such that the amount of heat transferred to the hot plate 29 is optimised. The first hot plate 21a may have the most heat transferred to it, with less heat transferred to each further hot plate within the device. There are diminishing returns if the number of hot plates is increased markedly (for example if there are more than ten hot plates) as by this stage the majority of the heat has been transferred to the hot plates nearest the beginning of the heating channel. At the end of the heating channel the majority of the heat has been extracted from the heating fluid. The heating fluid 29 then exits the heating channel. In some embodiments a pump may be used at the end of the heating channel to pump the heating fluid back to the position at which the heating fluid is heated. This may for example be at the top of the device where the heating fluid 29 may be positioned under a surface that is configured to absorb heat from the sun, and so heat up the heating fluid Alternatively the heating fluid 29 may be pumped towards a heating output of an industrial process.

In some embodiments the heating fluid 29 after use through the heating channel has had all of its heat extracted (or a substantial amount). At this point the heating fluid may now be cooling fluid 31. The cooling fluid may then be pumped through the cooling channel passing in thermal proximity with the cold plates 19. In this manner only one continuous circuit may be used, with the fluid being heated and cooled through use. This may advantageously reduce the complexity of the device.

Also shown on FIG. 8 is the conduction of heat on the hot plate 21 from the proximal 3 or distal 5 ends (where the heat transfer from the heating channel to the hot plate takes place) towards the centre 7 of the hot plate (where the thermoelectric module and the associated heat transfer takes place)

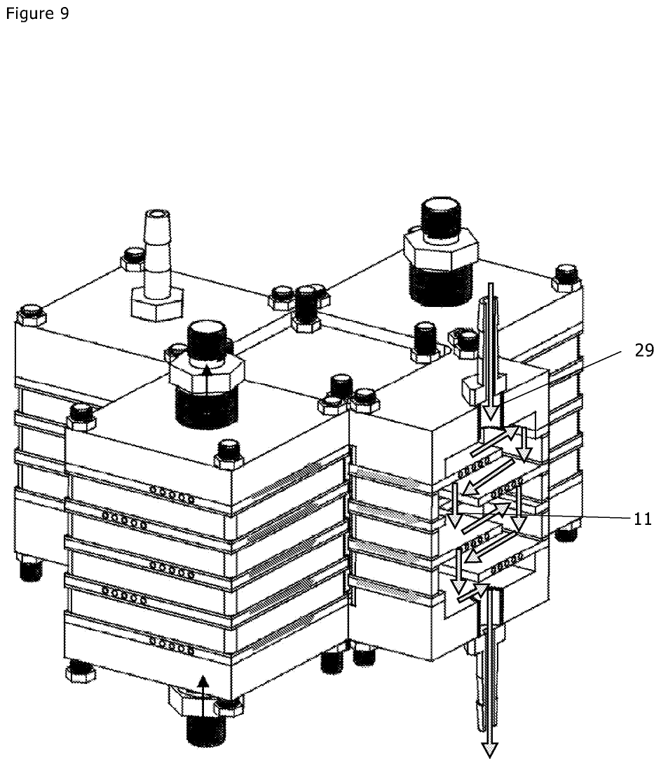

FIG. 9 is a cross section of the device showing the flow of cold fluid 31 in the cooling channel and the conduction of heat drawing heat from the cold plates 19. As shown in FIG. 9 this is a cross section through the windows 11 of the plates (as shown in FIG. 1). FIG. 9 differs to FIG. 8 in that the cooling channel, rather than the heating channel is shown. It is noted that this is substantially identical to the heating channel of FIG. 8, aside from the temperature of the fluid. The direction of the heating and cooling channels is shown as being opposite in FIGS. 8 and 9. This allows for increased temperature differentials. However, in some other embodiments the channels may be in the same direction if this is preferable due to local considerations (such as the heat source, and possibly the source of coolant).

The cooling channel is shown carrying cooling fluid thought the window 11 of each plate, and along each plate surface such that each of the cold plates is cooled by the cooling fluid. The cooling fluid then exits the device. The cooling fluid may be cooled, or it may be at room temperature, and so be nominally cool relative to the heating fluid.

Also shown is the cooling of the cooling fluid drawing thermal energy from the centre 7 of the cold plate 19. This decreases the temperature of the centre of the cold plate 19 (as the plate is attempting to reach a temperature equilibrium across its surface) and so helps create the temperature gradient across the centre of the plate in order to drive the electricity generation in the thermoelectric module 15.

It is noted that both the proximal 3 and distal 5 ends of the hot and cold plates may have the heating channels and cooling channels as shown in FIGS. 8 and 9. Alternatively only one of the proximal 3 or distal 5 ends of each plate may be connected to such a heating/cooling channel arrangement.

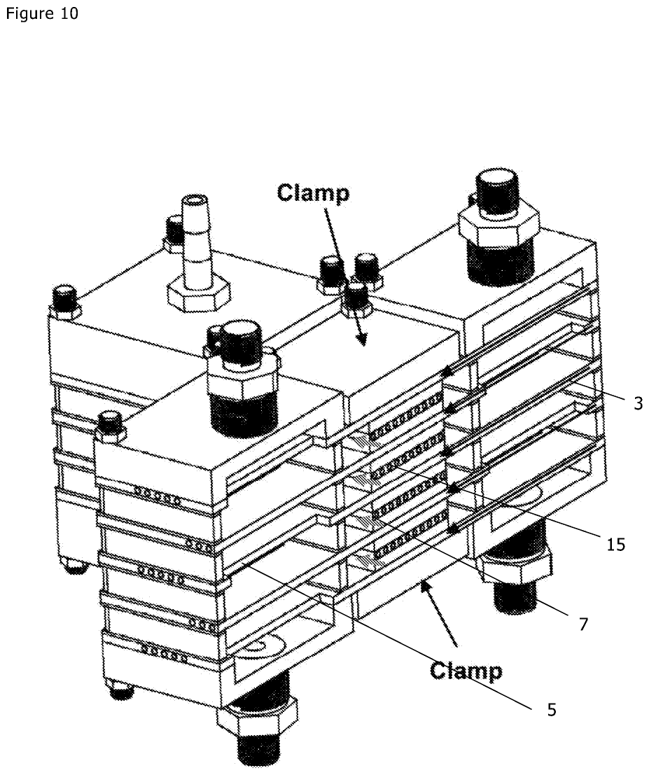

FIG. 10 shows heat flow in both the hot 21 and cold 19 plates. This shows heat being transferred towards the centre of the hot plates, and cold being transferred towards the centre of the cold plates (in reality of course cold being transferred to the centre of the cold plate is heat being transferred out of the centre of the cold plate, but this has the same effect).

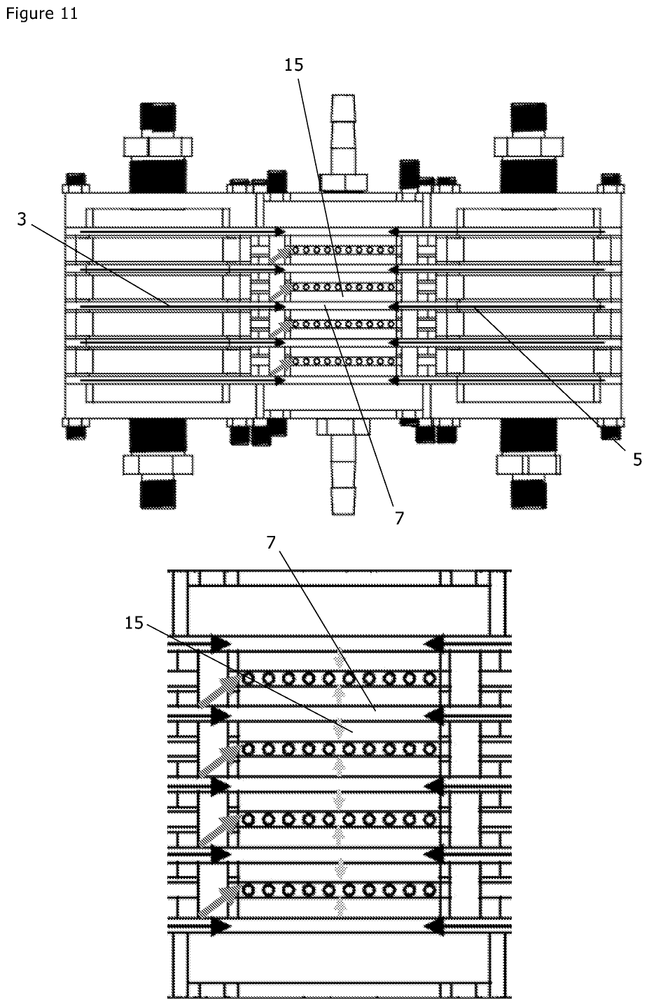

FIG. 11 shows the arrangement of the thermoelectric modules 15 within the device. The flow of cooling through the cold plate 19 is shown into the plane of the Figure. The flow of heat into the centre 7 of the hot plate 21 is shown in the Figure. The flow of heat through the thermoelectric modules 15 is also shown in FIG. 11. This shows that there is a thermal gradient flowing from the hot plate to the cold plate. The thermoelectric element converts the thermal energy form the thermal gradient into electric energy. FIG. 11 also shows that the thermal gradient between each adjacent coupled plates (cold and hot plates) inverts, so the position of the thermoelectric module inverts as well.

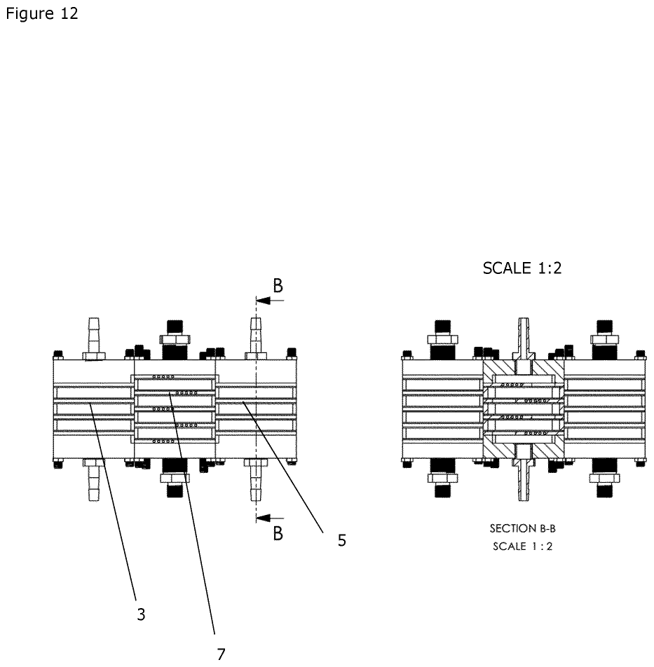

FIG. 12 shows a cross section of a complete device. This shows that there is a height offset between the cold and hot plates and that they are perpendicular to one another. The thermoelectric module is not shown in FIG. 12 as this may be provided separately.

It is noted that features of each of the embodiments described above, specifically the embodiment shown as well as those optional features described in the text above may be combined with the features of the other embodiments. For example, embodiments in which thermal spacers are used may be combined with any of the other optional features, for example the use of the heating fluid, once cooled by contact with each of the hot plates, as cooling fluid (rather than keeping the two fluid systems separate as per the other embodiments).

1. A static thermal generator for the generation of electricity from heat, wherein the thermal generator comprises:
a first hot plate, adjacent to a heating channel, the heating channel configured to carry a hot fluid such that the first hot plate is configured to be heated by the hot fluid;
a first cool plate, adjacent to a cooling channel, the cooling channel configured to carry a cool fluid such that the first cool plate is configured to be cooled by the cool fluid;
wherein the first hot plate comprises proximal, central and distal portions, and the first cool plate comprises proximal, central and distal portions;
wherein the first hot plate and first cool plate are arranged such that the central portion of the first hot plate and the central portion of the first cool plate overlap one another;
wherein the first hot plate and the first cool plate are positioned perpendicular to one another;
wherein the central portion of the first hot plate and the central portion of the first cool plate are separated by a space configured to house a thermoelectric module;
wherein the heating channel is configured such that when the hot fluid reaches the end of the heating channel the hot fluid exits the heating channel and is pumped to a position at which the hot fluid is re-heated.

2. The apparatus of claim 1, wherein one side of the thermoelectric module is cooled by the first cool plate, and the other side of the thermoelectric module is heated the first hot plate.

3. The apparatus of claim 1, wherein the space is configured such that when in situ said thermoelectric module contacts both the first hot plate and a second cool plate.

4. The apparatus of claim 1, wherein the first hot plate further comprises chambers, optionally wherein said chambers contain a vacuum, or optionally wherein said chambers contain a fluid or vapour, optionally wherein said vapour is at a low pressure, optionally wherein the vapour comprises water droplets.

5. The apparatus of claim 1, wherein the first cool plate further comprises chambers, optionally wherein said chambers contain a vacuum, or optionally wherein said chambers contain a fluid or vapour, optionally wherein said vapour is at a low pressure, optionally wherein the vapour comprises water droplets.

6. (canceled)

7. (canceled)

8. The apparatus of claim 1, further comprising a second hot plate comprising a proximal portion, central portion and distal portion, positioned in line with the first hot plate, and vertically offset from the first hot plate, wherein the first cool plate is positioned between the first hot plate and the second hot plate.

9. The apparatus of claim 8, wherein the second hot plate and first cool plate are arranged such that the central portion of the second hot plate and the central portion of the first cool plate overlap one another;
wherein the second hot plate and the first cool plate are positioned perpendicular to one another;
wherein the central portion of the second hot plate and the central portion of the first cool plate are separated by a space configured to house a second thermoelectric module.

10. The apparatus of claim 1, further comprising a second cool plate comprising a proximal portion, central portion and distal portion, positioned in line with the first cool plate, and vertically offset from the first cool plate, wherein the first hot plate is positioned between the first cool plate and the second cool plate.

11. The apparatus of claim 10, wherein the second cool plate and first hot plate are arranged such that the central portion of the second cool plate and the central portion of the first hot plate overlap one another;
wherein the second cool plate and the first hot plate are positioned perpendicular to one another;
wherein the central portion of the second cool plate and the central portion of the first hot plate are separated by a space configured to house a third thermoelectric module.

12. The apparatus of claim 1, further comprising a first thermoelectric module, optionally comprising a second thermoelectric module, and further optionally comprising a third thermoelectric module.

13. The apparatus of claim 1, wherein the central portion of the plates is profiled such that when overlapping one another one or more channels are created at the edge of the central portion, optionally wherein electric cables are positioned within the channels to connect to thermoelectric modules.

14. The apparatus of claim 8, wherein the heating channel passes from the first hot plate to the second hot plate.

15. The apparatus of claim 10, wherein the cooling channel passes form the first cool plate to the second cool plate.

16. The apparatus of claim 1, further comprising rods to connect the plates together such that they are secure.

17. The apparatus of claim 1, wherein the apparatus is within a sealed shell.

18. The apparatus of claim 1, wherein the plates are formed form copper or aluminium.

19. The apparatus of claim 1, wherein the heating fluid is oil, and optionally wherein the cooling fluid is water.

20. The apparatus of claim 1, wherein the heating fluid transfers waste heat from an industrial process, or wherein the heating fluid is heated via energy from the sun.

21. The apparatus of claim 17, further comprising a vat of heating fluid positioned adjacent the inside of the sealed shell, such that the heating fluid is warmed by energy from the sun.

22. The apparatus of claim 1, wherein the thermoelectric module is configured to transfer heat energy to electrical energy in the presence of a temperature differential.
